(19) United States
(12) Patent Application Publication
(10) Pub. No.: US 2025/0311640 A1
(43) Pub. Date: Oct. 2, 2025

(54) VERTICAL HALL ELEMENT

(71) Applicant: ABLIC Inc., Nagano (JP)

(72) Inventors: Satoshi SUZUKI, Nagano (JP); Shinji INAYOSHI, Nagano (JP)

(73) Assignee: ABLIC Inc., Nagano (JP)

(21) Appl. No.: 19/021,184

(22) Filed: Jan. 15, 2025

(30) Foreign Application Priority Data
Mar. 29, 2024 (JP) 2024-055207
Oct. 8, 2024 (JP) 2024-176292

(51) Int. Cl. H10N 52/00; G01R 33/07; H10N 52/80

(52) U.S. Cl. CPC H10N 52/101; G01R 33/077; H10N 52/80

(57) ABSTRACT

A vertical Hall element 100 formed on a surface of a P-type semiconductor substrate 10 includes: an N-type epitaxial layer 30 formed on the surface of the P-type semiconductor substrate 10; an electrode group 110, disposed on a surface of the N-type epitaxial layer 30 and formed by electrodes 111 to 115; a P-type well layer 50, disposed on the N-type epitaxial layer 30, and disposed in a ring shape on an outer periphery separate from the electrode group 110; and an outer peripheral electrode 120, formed along an upper surface of the P-type well layer 50 via an insulating film 60.

### CROSS-REFERENCE TO RELATED APPLICATION

This application claims the priority benefit of Japan application serial no. 2024-055207, filed on Mar. 29, 2024 and Japan application serial no. 2024-176292, filed on Oct. 8, 2024. The entirety of each of the above-mentioned patent applications is hereby incorporated by reference herein and made a part of this specification.

### BACKGROUND

### Technical Field

The present invention relates to a vertical Hall element.

### Description of Related Art

Hall elements can be easily formed on the surface of a semiconductor substrate and are used, as magnetic sensors, for various purposes capable of position detection and angle detection in a contactless manner.

Among the Hall elements, horizontal Hall elements that detect magnetic field components perpendicular to the surface of the semiconductor substrate are generally well known. However, various proposals have also been made for vertical Hall elements that detect magnetic field components parallel to the surface of the semiconductor substrate.

For example, a vertical Hall element has been proposed that can maintain high detection accuracy while suppressing variations in element sensitivity by selectively forming high-concentration regions on the substrate surface close to the P-N junction side of a diffusion layer that electrically partitions the inside of the substrate (see Japanese Patent Application Laid-open No. 2006-147710).

The invention provides a vertical Hall element capable of removing, with high accuracy, an offset voltage.

### SUMMARY

A vertical Hall element according to an embodiment of the present invention is: a vertical Hall element, formed on a surface of a semiconductor substrate having a first conductivity type. The vertical Hall element includes: an impurity diffusion layer, having a second conductivity type and formed on the surface of the semiconductor substrate; an electrode group, disposed on a surface of the impurity diffusion layer and formed by three or more electrodes; a well layer, having the first conductivity type, disposed on the impurity diffusion layer, and disposed in a ring shape on an outer periphery separate from the electrode group; and an outer peripheral electrode, formed along an upper surface of the well layer via an insulating film.

### BRIEF DESCRIPTION OF THE DRAWINGS

FIG. 1 is a schematic plan view illustrating a vertical Hall element according to the first embodiment of the invention.

FIG. 2 is a schematic cross-sectional view taken along a line II-II of FIG. 1.

FIG. 3 is a view illustrating an operation of the vertical Hall element according to the first embodiment.

FIG. 4 is a view illustrating an operation of the vertical Hall element according to the first embodiment.

FIG. 5 is a schematic plan view illustrating a depletion layer and current paths generated in Phase 2 of a spinning current method in the vertical Hall element of the embodiment.

FIG. 6 is a schematic cross-sectional view taken along a line VI-VI of FIG. 5.

FIG. 7 is a schematic plan view illustrating a depletion layer and current paths generated in Phase 3 of the spinning current method in the vertical Hall element of the embodiment.

FIG. 8 is a schematic cross-sectional view taken along a line VIII-VIII of FIG. 7.

FIG. 9 is a schematic plan view illustrating a depletion layer and current paths generated in Phase 4 of the spinning current method in the vertical Hall element of the embodiment.

FIG. 10 is a schematic cross-sectional view taken along a line IX-IX of FIG. 9.

FIG. 11 is a schematic plan view illustrating a depletion layer and current paths generated in Phase 1 of a spinning current method in a conventional vertical Hall element.

FIG. 12 is a schematic plan view illustrating a depletion layer and current paths generated in Phase 2 of the spinning current method in the conventional vertical Hall element.

FIG. 13 is a schematic plan view illustrating a depletion layer and current paths generated in Phase 3 of the spinning current method in the conventional vertical Hall element.

FIG. 14 is a schematic plan view illustrating a depletion layer and current paths generated in Phase 4 of the spinning current method in the conventional vertical Hall element.

FIG. 15 is a schematic cross-sectional view illustrating a vertical Hall element according to the second embodiment of the invention.

FIG. 16 is a schematic cross-sectional view illustrating a vertical Hall element according to the third embodiment of the invention.

FIG. 17 is a schematic cross-sectional view illustrating a vertical Hall element according to the fourth embodiment of the invention.

### DESCRIPTION OF THE EMBODIMENTS

A vertical Hall element according to an embodiment of the present invention is: a vertical Hall element, formed on a surface of a semiconductor substrate having a first conductivity type. The vertical Hall element includes: an impurity diffusion layer, having a second conductivity type and formed on the surface of the semiconductor substrate; an electrode group, disposed on a surface of the impurity diffusion layer and formed by three or more electrodes; a well layer, having the first conductivity type, disposed on the impurity diffusion layer, and disposed in a ring shape on an outer periphery separate from the electrode group; and an outer peripheral electrode, formed along an upper surface of the well layer via an insulating film.

According to an aspect of the invention, a vertical Hall element capable of removing, with high accuracy, an offset voltage can be provided.

The present invention is based on the knowledge that in vertical Hall elements, an offset voltage is more likely to occur than in horizontal Hall elements, and it is difficult to remove the offset voltage with high accuracy even when using the generally well-known spinning current method.

Specifically, the vertical Hall element has a structure in which an electrode group for supplying a drive current and detecting a Hall voltage is formed on a semiconductor substrate. In the vertical Hall element, the vertical structure of the semiconductor substrate is important, but it is difficult to form a structure with high geometric symmetry in the semiconductor process, and an offset voltage is more likely to occur than in a horizontal Hall element. The spinning current method is known as a method for removing offset voltage. The offset voltage caused by structural asymmetry due to manufacturing variations, etc., can be removed by calculating a correction value from the output voltage when changing the current flow between the respective electrodes in four phases.

However, when how the current flows between the respective electrodes in each phase of the spinning current method changes, the accuracy of removing the offset voltage may decrease due to differences in the distribution of the width of the depletion layer occurring on the surface of the inner peripheral part of the P-type well layer arranged around the outer periphery of the electrode group for element isolation. Thus, if the distance from the electrode group to the P-type well layer increases so as not to be affected by the distribution of the depletion layer width occurring on the surface of the inner peripheral part of the P-type well layer, not only does the chip size increase, but the drive current also disperses, and magnetic sensitivity decreases.

Thus, in the vertical Hall element of the embodiment, by reducing the depletion layer width near the surface by using an outer peripheral electrode provided above the P-type well layer disposed on the outer periphery of the electrode group, it is possible to remove the offset voltage with high accuracy.

The embodiments for implementing the present invention will be described in detail below with reference to the drawings.

In the drawings, the same reference numerals are assigned to the same structural parts, and repeated descriptions may be omitted. Also, in the drawings, the X direction, Y direction, and Z direction are orthogonal to each other. A direction including the X direction and the opposite direction (−X direction) of the X direction is referred to as the “X-axis direction”, the direction including the Y direction and the opposite direction (−Y direction) of the Y direction is referred to as the “Y-axis direction”, and the direction including the Z direction (upward) and the opposite direction (−Z direction, depth direction, downward) of the Z direction is referred to as the “Z-axis direction” (height direction, thickness direction). In this regard, in the following embodiments, the Z-direction side surface of each film may be referred to as the “surface”.

The drawings are schematic, and the ratios of width, length, and depth are not necessarily as illustrated in the drawings.

In the following description, the first conductivity type is described as P-type, and the second conductivity type is described as N-type.

### First Embodiment

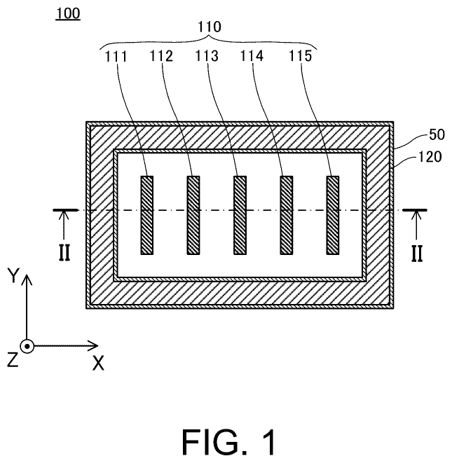

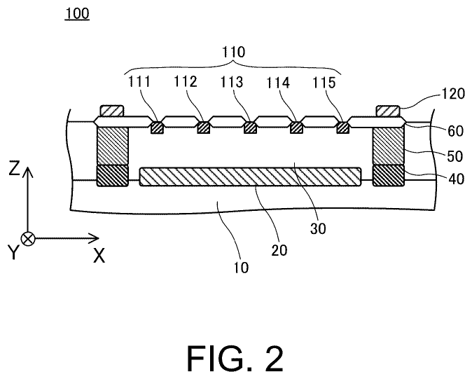

FIG. 1 is a schematic plan view illustrating a vertical Hall element according to the first embodiment of the invention. FIG. 2 is a schematic cross-sectional view taken along a line II-II of FIG. 1.

As illustrated in FIG. 1, the vertical Hall element 100 of the embodiment includes an electrode group 110, a P-type well layer 50 disposed in a ring shape around the outer periphery of the electrode group 110, and an outer peripheral electrode 120 disposed above the P-type well layer 50 along the ring-shaped P-type well layer 50.

The electrode group 110 is a group of electrodes for the vertical Hall element 100 to serve as a magnetic sensor. The electrode group 110 is formed of five electrodes 111 to 115.

When viewed from the Z-axis direction in a plan view, the electrodes 111 to 115 are disposed linearly on the surface of an N-type epitaxial layer 30, and are each formed in an N-type impurity region with a higher concentration than the N-type epitaxial layer 30. The electrodes 111 to 115 all have the same structure and are respectively rectangular when viewed in a plan view, and are arranged at equal intervals in a short-side direction thereof. As a result, the electrodes 111 to 115 have high structural symmetry. Thus, even when an external magnetic field is applied, the offset voltage that is output can be decreased.

Moreover, the electrodes 111 to 115 are respectively connected to a voltage source via wiring (not shown), and a necessary voltage is applied.

When the vertical Hall element 100 serves as a magnetic sensor, the electrodes 111, 113, and 115 become drive current supply electrodes, while the electrodes 112 and 114 become Hall voltage output electrodes. At the time of performing correction to remove the offset voltage by using the spinning current method, to obtain necessary output voltages Vout1 to Vout4, the drive current supply electrodes and the Hall voltage output electrodes may be interchanged.

The P-type well layer 50 is formed for element isolation and, when viewed in a plan view, is arranged in a rectangular ring shape on the outer periphery separated from the electrode group 110. The P-type well layer 50 is formed deep enough to contact a P-type buried layer 40, which will be described later. As a result, the vertical Hall element 100 is electrically isolated from another region (not shown) on the P-type semiconductor substrate 10 on the periphery of the vertical Hall element 100. In the region on the P-type semiconductor substrate 10 that is electrically isolated from the vertical Hall element 100, elements such as transistors are provided to form at least one of a circuit for processing output signals from the vertical Hall element 100 and a circuit for supplying signals to the vertical Hall element 100.

Moreover, because the shape of the P-type well layer 50 is ring-shaped, the P-type well layer 50 can prevent the current from the electrode group 110 from diffusing, and the magnetic sensitivity and the removal accuracy of the offset voltage can be increased. The inner peripheral part of the P-type well layer 50 may be located at a constant distance from the outer peripheral part of the electrode group 110. Accordingly, a constant electric field between the P-type well layer 50 and the electrode group 110 can be easily set.

The outer peripheral electrode 120 is formed above the P-type well layer 50 along the ring-shaped P-type well layer 50. By applying a predetermined positive voltage to the outer peripheral electrode 120, the width of the depletion layer near the surface the P-type well layer 50 on the inner peripheral side of can be reduced, and the magnetic offset can be suppressed.

Moreover, as illustrated in FIG. 2, the vertical Hall element 100 is formed on the surface of the P-type semiconductor substrate 10 and includes an N-type buried layer 20, the N-type epitaxial layer 30 as an impurity diffusion layer, a P-type buried layer 40, a P-type well layer 50, and an insulating film 60.

The P-type semiconductor substrate 10 is a silicon wafer to which P-type impurities are added.

The N-type buried layer 20 is formed near the boundary between the P-type semiconductor substrate 10 and the N-type epitaxial layer 30, and is disposed below the electrode group 110.

In the embodiment, the focus is on the depletion layer that occurs on the current path flowing in a region near the surface of the N-type epitaxial layer 30. However, a current path is also present that flows downward through the N-type epitaxial layer 30, passes through the inside of the N-type buried layer 20, and flows upward through the N-type epitaxial layer 30. In other words, the current flowing in the in-plane direction of the P-type semiconductor substrate 10 flows throughout the entire N-type buried layer 20 and N-type epitaxial layer 30. Thus, the N-type buried layer 20 and the N-type epitaxial layer 30 become a current path of the drive current at the time of operating as a magnetic sensor and serve as a magnetic sensing part.

The N-type epitaxial layer 30 is provided on the P-type semiconductor substrate 10, and N-type impurities are injected and diffused into the N-type epitaxial layer 30.

In addition, in the embodiment, the impurity concentration of the N-type epitaxial layer 30 is constant. However, it may also be configured so that the impurity concentration increases as the depth increases. Accordingly, the impurity concentration gradient can be adjusted so that the resistance value of the deepest current path becomes similar to the resistance value of the current path passing through a shallow position. Thus, the current path can expand in a more balanced manner, and the magnetic sensitivity of the vertical Hall element 100 can be increased.

The P-type buried layer 40 is formed near the boundary between the P-type semiconductor substrate 10 and the N-type epitaxial layer 30. The P-type buried layer 40 is disposed at a location separate from the N-type buried layer 20 and is disposed to contact the bottom surface of the P-type well layer 50.

The insulating film 60 is a silicon oxide film formed on the surface of the N-type epitaxial layer 30 by performing a local oxidation of silicon (LOCOS) process. The insulating film 60 is provided on the periphery of the electrode group 110, and between the lower surface of the outer peripheral electrode 120 and the upper surface of the P-type well layer 50.

As the insulating film 60, for example, from the perspective that a depletion layer may occur near the surface if the insulating film 60 is a film having a conductivity type, such as a P-type electrode isolation diffusion layer, a material that does not possess a conductivity type may be used.

Next, the manufacturing method of the vertical Hall element in the embodiment will be described.

First, N-type impurities or P-type impurities are selectively injected into regions where the N-type buried layer 20 and the P-type buried layer 40 are to be formed in the P-type semiconductor substrate 10. Then, the N-type epitaxial layer 30 containing N-type impurities is formed thereon. By selectively injecting and diffusing P-type impurities into the surface of the N-type epitaxial layer 30, the P-type well layer 50 is formed. Then, by using the insulating film 60 formed by performing the LOCOS process on the surface of the N-type epitaxial layer 30 as a mask, N-type impurities are injected at a high concentration from the surface of the N-type epitaxial layer 30 to form the electrode group 110. N-type impurities are injected at a high concentration into polysilicon to form the outer peripheral electrode 120 on the surface of the insulating film 60. In this way, the vertical Hall element 100 can be formed.

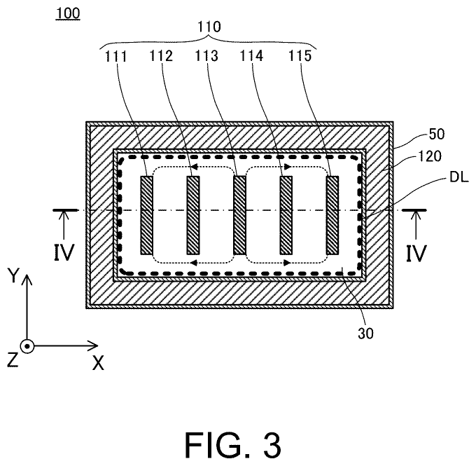

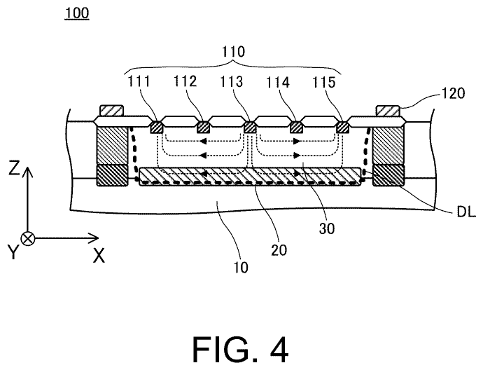

Next, the principle of detecting the −Y direction component of the external magnetic field in the vertical Hall element 100 will be described with reference to FIG. 3 and FIG. 4.

For the vertical Hall element 100 to perform magnetic detection, drive currents flow from the electrode 113 at the center towards the electrodes 111 and 115 on both ends in the +X direction and −X direction, respectively. As a result, the current paths become as illustrated with the dotted lines (thin lines) in the figure. In response to the drive currents, when an external magnetic field is applied in the −Y direction, Lorentz forces are generated in the +Z direction for charged particles of the drive current in the +X direction, and in the −Z direction for charged particles of the drive current in the −X direction, resulting in Hall voltages with potential differences whose positive/negative properties are reversed. The vertical Hall element 100 can detect, with good sensitivity, the external magnetic field applied from the −Y direction by outputting the voltage between the electrode 112 and the electrode 114, so as to add the absolute values of the potential differences.

The electrodes 114 and 115 are disposed to remove the offset voltage, and if the sole purpose is to detect the external magnetic field, three electrodes 111 to 113 may be sufficient.

Moreover, by applying a predetermined positive voltage to the outer peripheral electrode 120, the width of the depletion layer near the surface of the P-type well layer 50 on the inner peripheral side can be reduced and the current paths indicated with the dotted lines (thin lines) in FIG. 3 are not interfered. Thus, magnetic sensitivity can be suppressed from decreasing.

Next, the method of removing the offset voltage of the vertical Hall element 100 by using the spinning current method will be described with reference to FIG. 3 to FIG. 10.

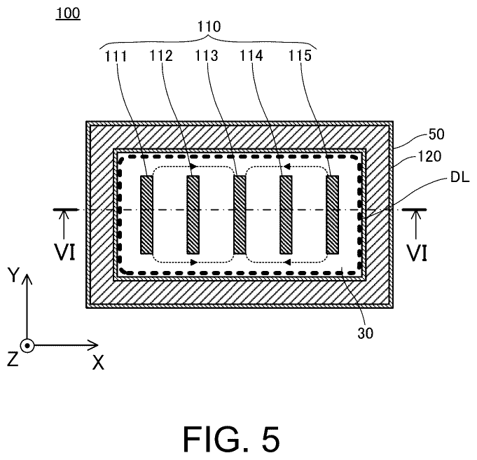

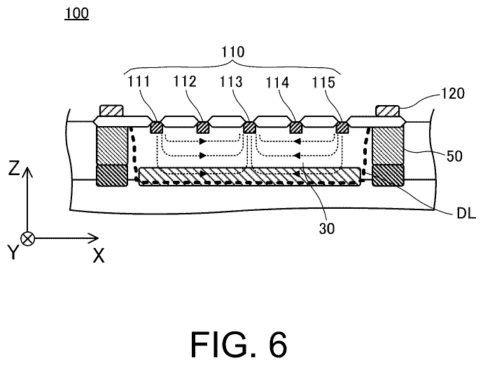

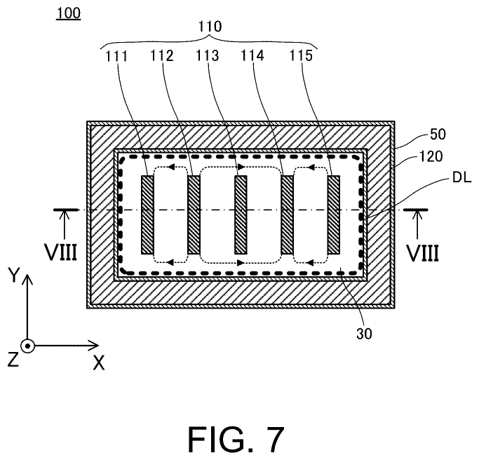

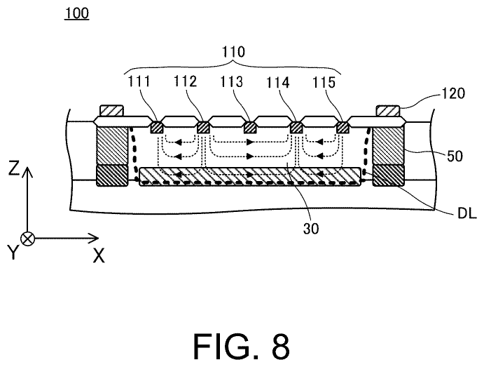

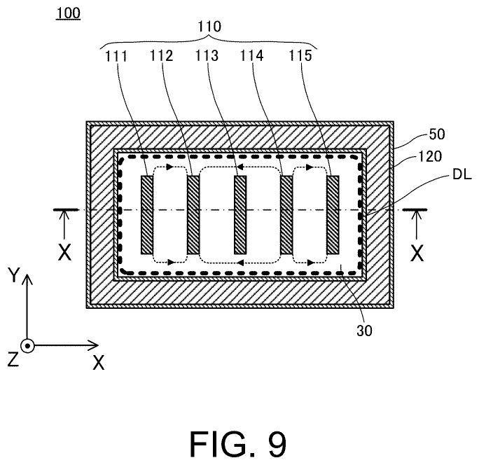

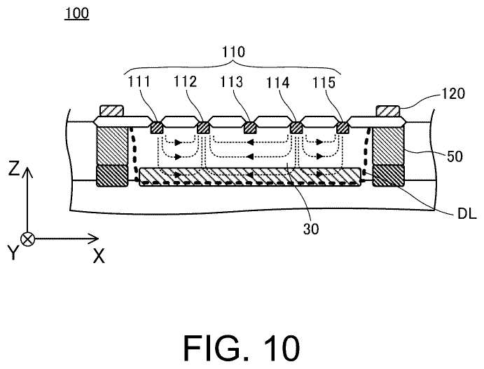

It should be noted that the changes in wiring connections at each phase can be realized by switching using switching elements, etc.
In Phase 1, as illustrated in FIG. 3 and FIG. 4, the electrodes 111, 113, and 115 are used as current supply electrodes, and currents flow from the electrode 113 to the electrodes 111 and 115, respectively. As a result, the current paths become as illustrated by the dotted lines (thin lines) in the figure, and the electrodes 112 and 114 are used as voltage output electrodes to obtain the voltage between the electrode 112 and the electrode 114 as an output voltage Vout1.
In Phase 2, as illustrated in FIG. 5 and FIG. 6, the directions in which the currents flow are reversed from those of FIG. 3 and FIG. 4, and the currents flow from the electrodes 111 and 115 to the electrode 113, respectively. As a result, the current paths become as illustrated by the dotted lines (thin lines) in the figure, and, similar to Phase 1, the electrodes 112 and 114 are used as voltage output electrodes to obtain the voltage between the electrode 112 and the electrode 114 as an output voltage Vout2.
In Phase 3, as illustrated in FIG. 7 and FIG. 8, the current supply electrodes and the voltage output electrodes are interchanged compared to FIG. 3 to FIG. 6. Current flows from the electrode 112 to the electrodes 111 and 114, respectively, and from the electrode 115 to the electrode 114. As a result, the current paths become as illustrated by the dotted lines (thin lines) in the figure, and the electrodes 111, 113, and 115 are used as voltage output electrodes to obtain the voltage between the electrode 113 and the electrode 111 or the electrode 115 as an output voltage Vout3.
In Phase 4, as illustrated in FIG. 9 and FIG. 10, the directions of current flows are reversed compared to those in FIG. 7 and FIG. 8. The currents flow from the electrode 114 to the electrodes 112 and 115, respectively, and from the electrode 111 to the electrode 112. As a result, the current paths become as illustrated by the dotted lines (thin lines) in the figure, and similar to Phase 3, the electrodes 111, 113, and 115 are used as voltage output electrodes to obtain the voltages between the electrode 113 and the electrodes 111 and 115 as an output voltage Vout4.

As illustrated in FIG. 3, FIG. 5, FIG. 7, and FIG. 9, even if the current flow method changes in each phase of the spinning current method, by applying a predetermined positive voltage to the outer peripheral electrode 120, the width of the depletion layer DL near the surface of the P-type well layer 50 on the inner peripheral side can be reduced. Thus, since the current paths are not interfered in the respective phases, by calculating correction values from the output voltages Vout1 to Vout4 to remove the offset voltage, the resistance value between the electrodes become equal in each phase, and the removal accuracy can be enhanced.

It should be noted that the depletion layer DL illustrated by the dotted lines (thick lines) in each figure represents a boundary on the side of the N-type region.

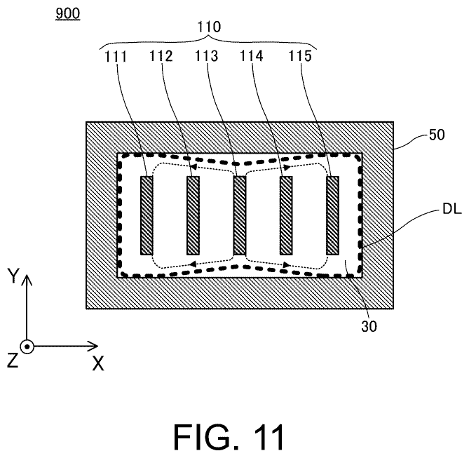

Then, to compare the vertical Hall element of the embodiment with a conventional vertical Hall element without the outer peripheral electrode, the depletion layer and the current paths that occur in the respective phases of the spinning current method in the conventional vertical Hall element is described with reference to FIG. 11 to FIG. 14.

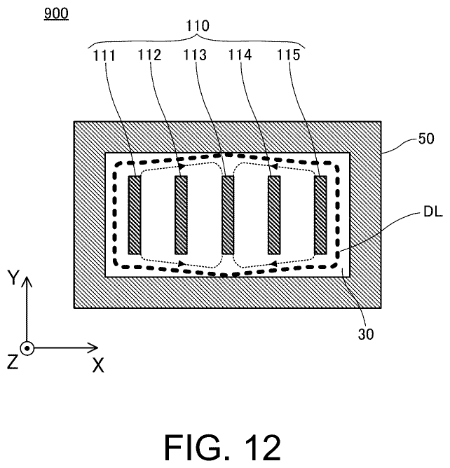

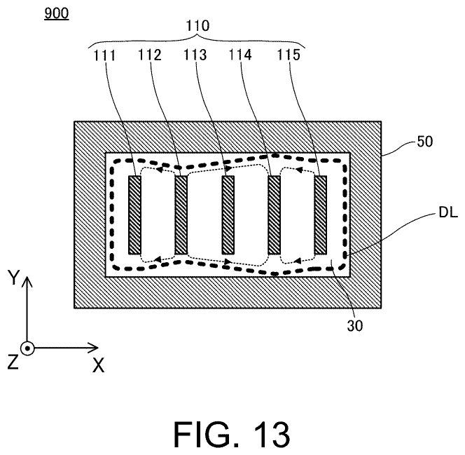

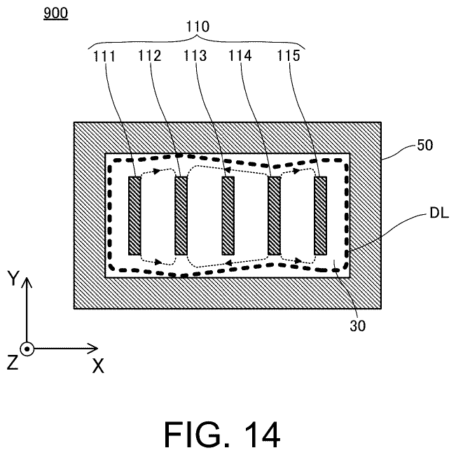

It should be noted that a conventional vertical Hall element 900, as illustrated in FIG. 11 to FIG. 14, is similar to the vertical Hall element 100 except that the outer peripheral electrode 120 is not disposed in the vertical Hall element 900.
In Phase 1, as illustrated in FIG. 11, the electrodes 111, 113, and 115 are used as current supply electrodes, and currents flow from the electrode 113 to the electrodes 111 and 115, respectively. At this time, because the voltages applied to the electrodes 111 to 115 are different, the electric fields between the electrodes 111 to 115 and the P-type well layer 50 whose potential is OV are different, and the width of the depletion layer DL that occurs on the surface of the N-type epitaxial layer 30 is not constant. In the state, the electrodes 112 and 114 are used as voltage output electrodes, and the voltage between the electrode 112 and the electrode 114 is obtained as the output voltage Vout1.
In Phase 2, as illustrated in FIG. 12, the directions in which the currents flow are reversed from those of FIG. 11, and the currents flow from the electrodes 111 and 115 to the electrode 113, respectively. At this time, because the voltages applied to the electrodes 111 to 115 are different, the electric fields between the electrodes 111 to 115 and the P-type well layer 50 whose potential is OV are different, the width of the depletion layer DL that occurs on the surface of the N-type epitaxial layer 30 is not constant, and the width also differs from the width of the depletion layer DL of Phase 1. In the state, the electrodes 112 and 114 are used as voltage output electrodes, and the voltage between the electrode 112 and the electrode 114 is obtained as the output voltage Vout2.
In Phase 3, as illustrated in FIG. 13, the current supply electrodes and the voltage output electrodes are interchanged compared to FIG. 11 to FIG. 12. Currents flow from the electrode 112 to the electrodes 111 and 114, respectively, and from the electrode 115 to the electrode 114. At this time, because the voltages applied to the electrodes 111 to 115 are different, the electric fields between the electrodes 111 to 115 and the P-type well layer 50 whose potential is OV are different, the width of the depletion layer DL that occurs on the surface of the N-type epitaxial layer 30 is not constant, and the width also differs from the width of the depletion layer DL of Phase 1 or 2. In the state, the electrodes 111, 113 and 115 are used as voltage output electrodes, and the voltages between the electrode 113 and the electrodes 111, 115 are obtained as the output voltage Vout3.
In Phase 4, as illustrated in FIG. 14, the directions of current flows are reversed compared to those in FIG. 13. The currents flow from the electrode 114 to the electrodes 112 and 115, respectively, and from the electrode 111 to the electrode 112. At this time, because the voltages applied to the electrodes 111 to 115 are different, the electric fields between the electrodes 111 to 115 and the P-type well layer 50 whose potential is OV are different, the width of the depletion layer DL that occurs on the surface of the N-type epitaxial layer 30 is not constant, and the width also differs from the width of the depletion layer DL of any one of Phases 1 to 3. In the state, the electrodes 111, 113 and 115 are used as voltage output electrodes, and the voltages between the electrode 113 and the electrodes 111, 115 are obtained as the output voltage Vout4.

In this way, in the conventional vertical Hall element 900, when the way in which the current flows is changed in each phase, the width of the depletion layer DL on the surface of the N-type epitaxial layer 30, which serves as the current path, differs in each phase and does not remain constant. As a result, in the spinning current method, the distribution of the depletion layer width on the surface of the N-type epitaxial layer 30, which serves as the current path, differs, the resistance values between the electrodes change, and the removal accuracy is reduced.

Thus, in the vertical Hall element 100 of the embodiment, by applying a predetermined positive voltage to the outer peripheral electrode 120, it is possible to reduce the width of the depletion layer near the surface of the P-type well layer 50 on the inner peripheral side, and does not interfere with the current path indicated by the dotted line (thin line) in FIG. 3. As a result, the vertical Hall element 100 can remove the offset voltage with high accuracy.

### Second Embodiment

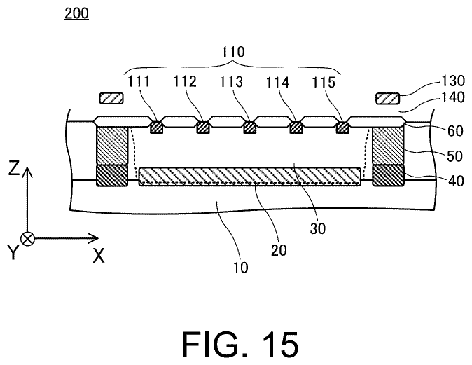

FIG. 15 is a schematic cross-sectional view illustrating a vertical Hall element according to the second embodiment of the invention.

As illustrated in FIG. 15, a vertical Hall element 200 in the embodiment is similar to the vertical Hall element 100, except that the outer peripheral electrode 130 is formed inside an interlayer insulating film 140 formed on the upper surface of the insulating film 60 in the vertical Hall element 100.

The following describes the outer peripheral electrode 130 and the interlayer insulating film 140, which are differences from the vertical Hall element 100.

The outer peripheral electrode 130 is formed separately from the upper surface of the insulating film 60. The outer peripheral electrode 130 is formed by injecting, at a high concentration, N-type impurities into polysilicon. The outer peripheral electrode 130 may also be formed as a metal layer.

The interlayer insulating film 140 is formed over the entire upper surface of the insulating film 60 and the electrode group 110. In the embodiment, the interlayer insulating film 140 is a silicon oxide film to which phosphorus and boron are added (also referred to as a boro-phospho silicate glass (BPSG) film).

Even for the vertical Hall element 200 in such structure, similar to the vertical Hall element 100, by applying a predetermined positive voltage to the outer peripheral electrode 120, the width of the depletion layer near the surface of the P-type well layer 50 on the inner peripheral side can be reduced. As a result, the vertical Hall element 200 can remove the offset voltage with high accuracy without interfering with the current path.

### Third Embodiment

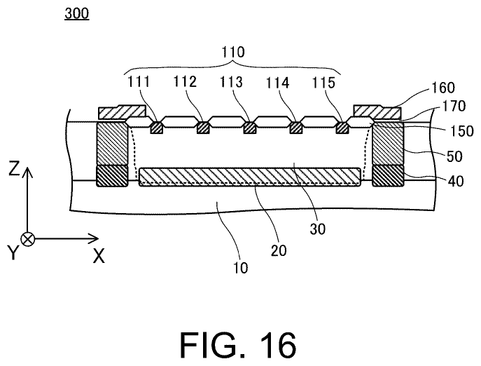

FIG. 16 is a schematic cross-sectional view illustrating a vertical Hall element according to the third embodiment of the invention.

As illustrated in FIG. 16, a vertical Hall element 300 in the embodiment is similar to the vertical Hall element 100, except that, the insulating film 60 in the vertical Hall element 100 is replaced with an insulating film 150 not covering the P-type well layer 50, and an outer peripheral electrode 160 is formed to cover the insulating film 150 and the P-type well layer 50.

The following describes the outer peripheral electrode 160 and an oxidization film 170, which is a difference from the vertical Hall element 100.

The outer peripheral electrode 160 is formed to cover the P-type well layer 50 and the insulating film 150, and the oxidization film 170 is formed between the outer peripheral electrode 160 and the P-type well layer 50. The outer peripheral electrode 160 is formed to extend over the N-type epitaxial layer 30 to cover a portion of the insulating film 150.

The oxidization film 170 should be as thin as possible, such as being about 15 nm, to facilitate the bending of the energy band due to the work function difference between the P-type well layer 50 and the outer peripheral electrode 160.

As a process of forming the oxidization film 170, an example may include a film formation process similar to that of a gate oxidization film.

In this way, the vertical Hall element 300 utilizes the bending of the energy band due to the work function difference between the P-type well layer 50 and the outer peripheral electrode 160 and allows the surface of the P-type well layer 50 to become closer to N-type without applying a voltage to the outer peripheral electrode 160. As a result, the vertical Hall element 300 can reduce the width of the depletion layer near the surface of the P-type well layer 50 on the inner peripheral side.

### Fourth Embodiment

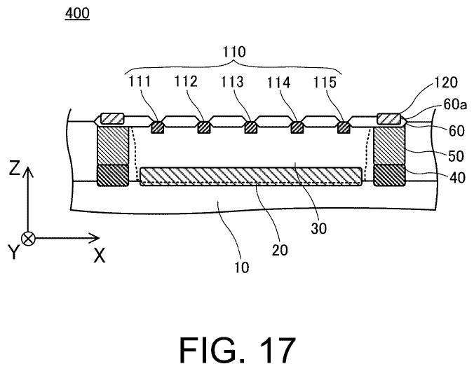

FIG. 17 is a schematic cross-sectional view illustrating a vertical Hall element according to the fourth embodiment of the invention.

As illustrated in FIG. 17, a vertical Hall element 400 in the embodiment is similar to the vertical Hall element 100, except that the outer peripheral electrode 120 is formed in a groove part 60a on the upper surface of the insulating film 60 in the vertical Hall element 100.

The following describes the groove part 60a on the upper surface of the insulating film 60, which is a difference from the vertical Hall element 100.

The groove part 60a is formed by etching the upper surface of the insulating film 60. The outer peripheral electrode 120 is formed by injecting N-type impurities at a high concentration into polysilicon formed in the groove part 60a.

Even for the vertical Hall element 400 in such structure, similar to the vertical Hall element 100, by applying a predetermined positive voltage to the outer peripheral electrode 120, the width of the depletion layer near the surface of the P-type well layer 50 on the inner peripheral side can be reduced. As a result, the vertical Hall element 200 can remove the offset voltage with high accuracy without interfering with the current path.

As described above, the vertical Hall element according to the embodiments of the present invention includes an impurity diffusion layer of a second conductivity type formed on the surface of a semiconductor substrate of a first conductivity type, and an electrode group formed by three or more electrodes and disposed on the surface of the impurity diffusion layer. The vertical Hall element further includes a well layer of the first conductivity type disposed in the impurity diffusion layer and disposed in a ring shape on the outer periphery separate from the electrode group, and an outer peripheral electrode formed along the upper surface of the well layer via an insulating film.

Accordingly, the vertical Hall element can reduce the width of the depletion layer near the surface of the P-type well layer on the inner peripheral side, and does not interfere with the current path. Thus, the vertical Hall element can remove the offset voltage with high accuracy.

The present invention has been described with reference to specific embodiments. However, the present invention is not limited to these embodiments and can be modified in various ways within the scope of the present invention without departing from its spirit.

For example, while the first conductivity type has been described as P-type and the second conductivity type as N-type, the conductivity types can be interchanged. That is, the first conductivity type may be described as N-type and the second conductivity type may be described as P-type.

In addition, while the number of electrodes in the electrode group is set to five in each of the embodiments, the invention is not limited thereto. For example, in the case where the offset voltage can be lowered or accepted to the extent that removal of the offset voltage by the spinning current method is unnecessary, at least three electrodes consisting of two drive current supply electrodes and one Hall voltage output electrode are sufficient. In other words, with a configuration not forming the electrodes 114 and 115 of the vertical Hall element 100 illustrated in FIG. 1, etc., the layout area can be reduced, enabling miniaturization of the vertical Hall element.

What is claimed is:

1. A vertical Hall element, formed on a surface of a semiconductor substrate having a first conductivity type, the vertical Hall element comprising:
an impurity diffusion layer, having a second conductivity type and formed on the surface of the semiconductor substrate;
an electrode group, disposed on a surface of the impurity diffusion layer and formed by three or more electrodes;
a well layer, having the first conductivity type, disposed on the impurity diffusion layer, and disposed in a ring shape on an outer periphery separate from the electrode group; and
an outer peripheral electrode, formed along an upper surface of the well layer via an insulating film.

2. The vertical Hall element as claimed in claim 1, wherein the outer peripheral electrode is able to be applied with a predetermined voltage.

3. The vertical Hall element as claimed in claim 1, wherein the outer peripheral electrode is formed to cover over the impurity diffusion layer on a side of the inner peripheral part of the well layer.

4. The vertical Hall element as claimed in claim 1, wherein the outer peripheral electrode is formed in a groove part of the insulating film.

5. The vertical Hall element as claimed in claim 1, wherein an inner peripheral part of the well layer is located at a distance from an outer peripheral part of the electrode group.

6. The vertical Hall element as claimed in claim 1, wherein an impurity concentration of the impurity diffusion layer increases as depth increases.

7. The vertical Hall element as claimed in claim 1, wherein, when viewed in a plan view, the electrode group is disposed linearly.
